(19) United States
(12) Patent Application Publication
(10) Pub. No.: US 2004/0174165 A1
(43) Pub. Date: Sep. 9, 2004

(54) Leakage flux detector

(76) Inventors: Hideyuki Yamane, Hiroshima-shi (JP); Yoshimi Enoki, Hiroshima-shi (JP); Shigeo Honda, Matsue-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/791,865

(22) Filed: Mar. 4, 2004

(30) Foreign Application Priority Data
Mar. 7, 2003 (JP) 2003-61870

(51) Int. Cl. G01R 33/09; G01R 33/06

(52) U.S. Cl. 324/252; 428/692

(57) ABSTRACT

A leakage flux detector includes a substrate, a sensing layer formed on the substrate for detecting presence or absence of a magnetic force, and two terminal layers formed on the substrate and jointed to the sensing layer.

### BACKGROUND OF THE INVENTION

1. Field of the Invention

The present invention relates to a leakage flux detector suited for use in detecting the presence or absence of a leakage flux in a wide range.

2. Description of the Related Art

A flux meter, a gauss meter or the like has been hitherto used to measure how a magnetic field is present around an object such as, for example, a permanent magnet, an electric appliance having a magnet accommodated therein, or the like. Measurement is generally made by first positioning a sensor such as a Hall element at a predetermined measuring point around the object and by subsequently manually changing the measuring point. The flux density measured by the gauss meter or the like is plotted for each measuring point so that the state of the magnetic field around the object may be visually recognized.

However, this method of measuring the magnetic field requires the sensor to be moved from the first measuring point to the last one in order and, hence, measurement needs a considerable period of time. Because of this, this method is not suitable for capturing changes of the magnetic field around the object on real-time basis. Furthermore, in the case where the measuring points are manually changed, the positioning of the sensor on each measuring point is not easy.

To solve this problem, it is conceivable that a relatively wide magnetic field is measured collectively by a number of sensors arrayed on a predetermined plane. Such sensors make it possible to measure the magnetic field at respective measuring points within a short period of time without moving each of them. It is, however, necessary for each sensor to be connected to lead wires, through which a driving voltage or a driving current is supplied, or an output current or an output voltage is detected. That is, a number of lead wires or complicated wiring is required for each sensor and, hence, the provision of a number of sensors on the predetermined plane is not practical.

In view of the above, the applicants of this application have proposed a convenient two-dimensional magnetic sensor in which a plurality of generally planar sensing layers are stacked one upon another with a conductive layer interposed between adjacent sensing layers. Each of the sensing layers exhibits a giant magneto-resistance effect caused by a tunnel effect, and one of them is composed of a granular film made of an insulating oxide and containing metallic particles (see, for example, Japanese Laid-Open Patent Publication No. 2002-40117).

The two-dimensional magnetic sensor as discussed above can measure a magnetic field in two- or three-dimensional directions at a plurality of measuring points without moving the sensor within the magnetic field to be measured. In addition, this magnetic sensor can make an analysis of a magnetic field in a wide range on not only the strength of the magnetic field but the directions of lines of magnetic force within a short period of time.

Such a two-dimensional magnetic sensor is used to readily measure a magnetic field at each measuring point within a short period of time, but it is complicated in structure for the purpose of merely detecting a magnetic field in a wide range. For this reason, a magnetic sensor capable of readily detecting a magnetic field with a simple structure has been desired.

### SUMMARY OF THE INVENTION

The present invention has been developed to overcome the above-described disadvantages.

It is accordingly an objective of the present invention to provide a leakage flux detector of a simple structure that can detect a magnetic field in a wide range.

In accomplishing the above and other objectives, the leakage flux detector according to the present invention includes a substrate, a sensing layer formed on the substrate for detecting the presence or absence of a magnetic force, and two terminal layers formed on the substrate and jointed to the sensing layer.

Although this structure is simple, it enables the entire surface of the sensing layer to be used as a sensor and can detect the presence or absence of a magnetic force (absolute value) greater than a predetermined value at every point within the entire surface of the sensing layer.

The two terminal layers are formed along opposite side edges of the sensing layer extending generally parallel to each other. This improves and stabilizes the sensitivity of the sensing layer.

The sensing layer includes a magneto-resistive film of a granular film structure.

### BRIEF DESCRIPTION OF THE DRAWINGS

The above and other objectives and features of the present invention will become more apparent from the following description of a preferred embodiment thereof with reference to the accompanying drawings, throughout which like parts are designated by like reference numerals, and wherein:

FIG. 1 is a top plan view of a leakage flux detector according to the present invention;

FIG. 2 is a cross-sectional view taken along the line II-II in FIG. 1;

FIG. 3 is an enlarged schematic view of a granular film that constitutes a sensing layer employed in the leakage flux detector of FIG. 1;

FIGS. 4A and 4B are schematic views used for explaining the characteristics of the granular film; and

FIG. 5 is a graph indicating a relationship between the magnetic field intensity and the resistance of the granular film.

### DETAILED DESCRIPTION OF THE PREFERRED EMBODIMENTS

This application is based on an application No. 2003-61870 filed Mar. 7, 2003 in Japan, the content of which is herein expressly incorporated by reference in its entirety.

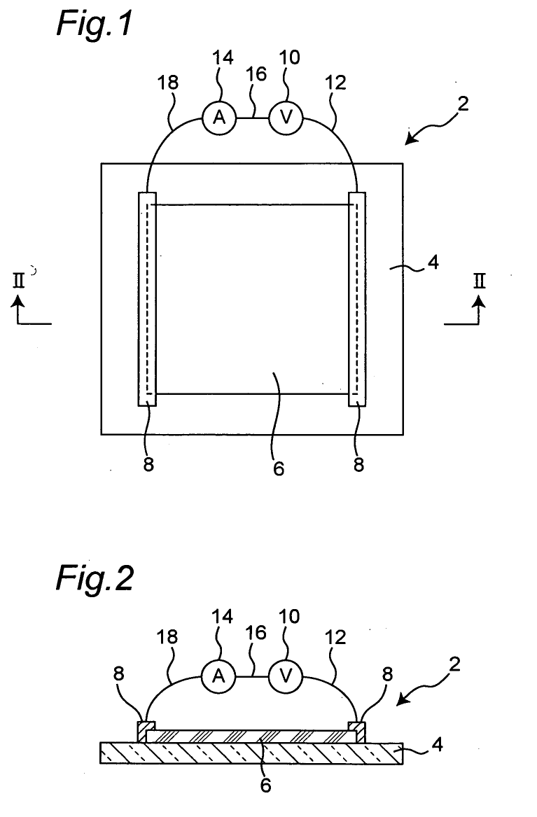

FIGS. 1 and 2 depict a leakage flux detector 2 embodying the present invention, which includes a glass substrate 4, a generally rectangular sensing layer,6 overlaid on the glass substrate 4, and two generally straight terminal layers 8 formed on the glass substrate 4 so as to extend generally parallel to each other along two opposite side edges of the sensing layer 6.

The sensing layer 6 is made of a generally planar magneto-resistive film having an arbitrary size, which has a giant magneto-resistance effect (GMR effect) of a magnitude offering a maximum magneto-resistance Ratio (maximum MR ratio) of several tens percent. In applications where a single magneto-resistive film is used to detect a wide magnetic field, it is required to have a giant magneto-resistance effect offering a large maximum MR ratio.

A typical example of the sensing layer 6 is a granular film in which a magnetic material such as Fe, Co, Ni, etc. is dispersed in a non-magnetic metal such as Ag or Au. Another typical example of the sensing layer 6 is of a tunneling granular film structure having a tunnel effect for allowing an electric current to flow therethrough when the voltage applied thereto is greater than a predetermined value wherein a magnetic material such as Fe, Co, Ni, etc. is dispersed in an insulating non-magnetic oxide such as SiO₂, ZnO₂, ZrO, Al₂O₃, MgO, etc.

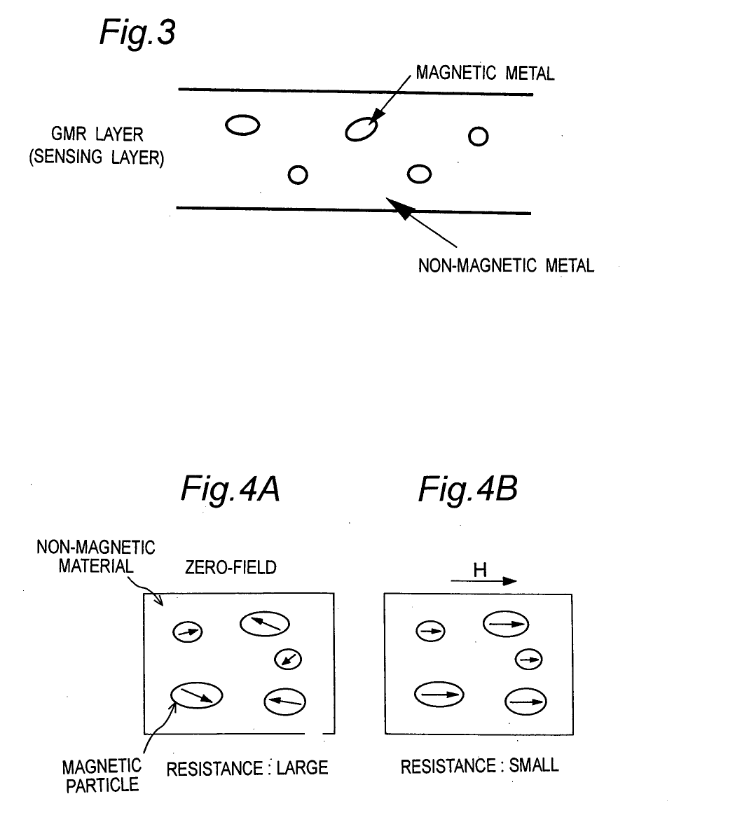

FIG. 3 schematically depicts a magneto-resistive film of the granular film structure in which metallic particles made of a magnetic material such as Fe, Co, Ni, etc. is contained in the aforementioned insulating oxide or a non-magnetic metal such as Ag or Au.

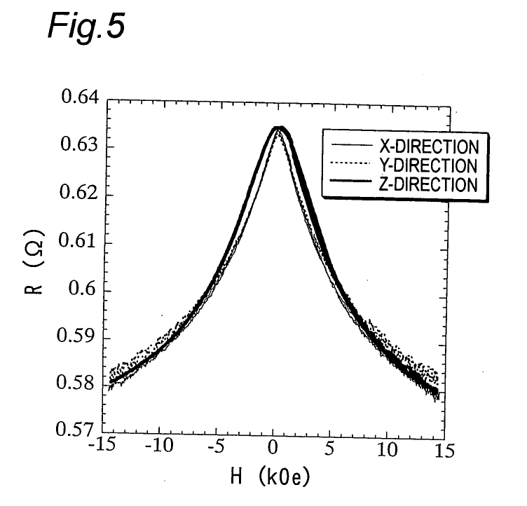

As shown in FIGS. 4A and 4B and FIG. 5, the magneto-resistive film of FIG. 3 has, in a zero-field, a relatively large resistance and characteristics in which the directions of magnetization of the metallic particles (magnetic particles) are irregular. Upon application of a magnetic field, the directions of magnetization of the metallic particles are oriented in the same direction, and the resistance of the magneto-resistive film reduces.

It is to be noted here that FIG. 5 is a graph obtained by measuring a sample of 5 mm×5 mm×1 mm T using a direct-current 4-terminal method with a VSM (vibrating sample magnetometer) manufactured by Riken Denshi Co., Ltd. This graph reveals that the sample has substantially the same sensitivity in three directions of X, Y, and Z. Accordingly, lines of magnetic force in all directions can be measured using only a single sheet of magneto-resistive film of the granular film structure.

Each terminal layer 8 is formed on a surface of the sensing layer 6 and joined to the two opposite side edges of the sensing layer 6. Each terminal layer 8 is made of a conductive material such as, for example, Cu or the like.

Although in the above-described embodiment the two terminal layers 8 have been described as being formed on one surface of the sensing layer 6 in the manner such as shown in FIGS. 1 and 2, the two terminal layers 8 are not always formed on the same surface of the sensing layer 6. One of the terminal layers 8 may be formed on the lower surface of the sensing layer 6 along one side edge thereof, with the other of the terminal layers 8 formed on the upper surface of the sensing layer 6 along the opposite side edge thereof.

Although the manner in which the sensing layer 6 made of a magneto-resistive film and the two generally straight terminal layers 8 are formed on the glass substrate 4 is optional, sputtering, vacuum deposition or the like can be preferably used. If sputtering or the like is employed, a mask formed into a predetermined pattern can be used to form the terminal layers 8.

A driving circuit and a detecting circuit are connected between the two terminal layers 8. In the example shown in FIGS. 1 and 2, a constant voltage circuit 10 for supplying driving power at a constant voltage and an ammeter 14 are utilized as the driving circuit and the detecting circuit, respectively. The constant voltage circuit 10 is connected to one of the terminal layers 8 via a lead wire 12, while the ammeter 14 is connected to the constant voltage circuit. 10 via a lead wire 16 and to the other of the terminal layers 8 via a lead wire 18.

According to this embodiment, when a predetermined driving voltage is applied by the constant voltage circuit 10, an electric current flows from one of the terminal layers 8 to the other of the terminal layers 8 via the sensing layer 6. At this moment, the resistance of the magneto-resistive film that constitutes the sensing layer 6 changes depending on the presence or absence of a magnetic force, which can be detected by the ammeter 14.

The setting value can be appropriately determined based on a relationship between the magnetic field and the resistance as shown in FIG. 5.

Although in this embodiment the presence or absence of a magnetic field greater than a predetermined value is determined by applying a predetermined voltage to the leakage flux detector using the constant voltage circuit 10 and by detecting an electric current which flows from one of the terminal layers 8 to the other of the terminal layers 8 via the sensing layer 6 using the ammeter 14, a constant current circuit and a voltmeter may be respectively used in place of the constant voltage circuit 10 and the ammeter 14. In this case, the leakage flux detector is activated at a constant current while the voltage is measured by the voltmeter, making it possible to detect a magnetic field greater than a predetermined value.

Although the present invention has been fully described by way of examples with reference to the accompanying drawings, it is to be noted here that various changes and modifications will be apparent to those skilled in the art. Therefore, unless such changes and modifications otherwise depart from the spirit and scope of the present invention, they should be construed as being included therein.

What is claimed is:

1. A leakage flux detector comprising:
a substrate;
a sensing layer formed on the substrate for detecting presence or absence of a magnetic force; and
two terminal layers formed on the substrate and jointed to the sensing layer.

2. The leakage flux detector according to claim 1, wherein the two terminal layers are formed along opposite side edges of the sensing layer extending generally parallel to each other.

3. The leakage flux detector according to claim 1, wherein the sensing layer comprises a magneto-resistive film of a granular film structure.

4. The leakage flux detector according to claim 2, wherein the sensing layer comprises a magneto-resistive film of a granular film structure.
